(19) United States
(12) Patent Application Publication
(10) Pub. No.: US 2014/0092555 A1
(43) Pub. Date: Apr. 3, 2014

(54) HEAT-DISSIPATING FOR ELECTRONIC DEVICE

(71) Applicant: NVIDIA CORPORATION, Santa Clara, CA (US)

(72) Inventors: Jun HUA, Shenzhen (CN); Qiang CHEN, Shenzhen (CN); DongMei NIU, Shenzhen (CN)

(73) Assignee: NVIDIA CORPORATION, Santa Clara, CA (US)

(21) Appl. No.: 14/034,886

(22) Filed: Sep. 24, 2013

(30) Foreign Application Priority Data
Sep. 29, 2012 (CN) 201210374483.2

(51) Int. Cl. H05K 7/20

(52) U.S. Cl. CPC H05K 7/20136; H05K 7/20409
USPC 361/695; 174/50; 361/688; 361/714

(57) ABSTRACT

Various embodiments in accordance with the present invention provide a housing, a support, and a heat-dissipating assembly for an electronic device. A heat-dissipating opening is disposed on a rear cover of the housing. The heat-dissipating opening is disposed in correspondence with a heat-generating means of the electronic device. A covering means is also disposed on the rear cover of the housing, and the covering means is configured to enable the heat-dissipating opening to be opened and closed. The housing for the electronic device enables the covering means to be operated according to the heat condition of the electronic device, and prevents significant heat accumulation in the electronic device.

### CROSS-REFERENCE TO RELATED APPLICATION

This patent application claims the benefit and priority of the co-pending Chinese Patent Application No. 201210374483.2, filed on Sep. 29, 2012, by Jun HUA et al., Attorney Docket Number P12838207, which is hereby incorporated by reference in its entirety.

### BACKGROUND

Heat dissipation is one of the prime reasons for limiting the development of a flat electronic device (including a tablet, a flat mobile phone such as iPhone, etc.) during the design of the flat electronic device. The housing of such flat electronic device is usually designed to be sealed for reasons that there is a need to protect the interior electronic elements and prevent dust from entering, but which causes heat accumulation in the interior of the flat electronic device. In order to prevent decreasing the life of the electronic elements (even burning down) caused by the significant heat accumulated in the flat electronic device, the processing speed of the prime heat-dissipating element (such as processor, etc.) is usually reduced, which limits the performance of the flat electronic device.

### SUMMARY

Therefore, there is a need of providing a housing, a support, and a heat-dissipating assembly (or system) for a flat electronic device to solve the above problem in the conventional art.

In order to solving the above problem, a housing for a flat electronic device is provided by an embodiment in accordance with the present invention, wherein a heat-dissipating opening is disposed on a rear cover of the housing. The heat-dissipating opening is disposed in correspondence with a heat-generating means of the flat electronic device. A covering means is also disposed on the rear cover of the housing, and the covering means is configured to enable the heat-dissipating opening to be opened and closed.

Preferably, in an embodiment, the covering means is slidably disposed on the housing. The heat-dissipating opening is open when the covering means slides to a first position, and the heat-dissipating opening is closed when the covering means slides to a second position.

Preferably, in an embodiment, a sliding groove is disposed on an inner surface of the rear cover of the housing. The covering means comprises a cover and a switch. The cover is slidably disposed in the sliding groove. The switch is disposed on the cover and extends from an interior of the rear cover to an exterior of the rear cover so as to drive the cover to slide between the first position and the second position.

Preferably, in an embodiment, the covering means further comprises a position-limiting component for limiting the position of the switch when the cover is in the first position and the second position, respectively.

Preferably, in an embodiment, a heat-conducting component is disposed in the heat-dissipating opening such that the heat-conducting component is against the heat-generating means when the housing is mounted to the flat electronic device.

Preferably, in an embodiment, a heat-dissipating means is disposed on a support which is used for supporting the flat electronic device, and the position of the heat-dissipating means corresponds to the position of a heat-dissipating opening of a rear cover of a housing of the flat electronic device when the flat electronic device is placed on the support.

Preferably, in an embodiment, the heat-dissipating means is a fan.

Preferably, in an embodiment, the heat-dissipating means are fins.

Preferably, in an embodiment, the fins are projected beyond a supporting surface of the support which is used for supporting the flat electronic device.

Preferably, in an embodiment, a power interface is disposed on the support. Through the power interface, the flat electronic device placed on the support is able to be charged.

A heat-dissipating assembly (or system) for a flat electronic device is also provided by an embodiment in accordance with the present invention, which comprises a housing for a flat electronic device and a support for the flat electronic device. A heat-dissipating opening is disposed on a rear cover of the housing. The heat-dissipating opening is disposed in correspondence with a heat-generating means of the flat electronic device. A covering means is also disposed on the rear cover of the housing, and the covering means is configured to enable the heat-dissipating opening to be opened and closed. A heat-dissipating means is disposed on the support which is used for supporting the flat electronic device, and the position of the heat-dissipating means corresponds to the position of the heat-dissipating opening when the flat electronic device is placed on the support.

Preferably, in an embodiment, the covering means is slidably disposed on the housing. The heat-dissipating opening is open when the covering means slides to a first position, and the heat-dissipating opening is closed when the covering means slides to a second position.

Preferably, in an embodiment, a sliding groove is disposed on an inner surface of the rear cover of the housing. The covering means comprises a cover and a switch. The cover is slidably disposed in the sliding groove. The switch is disposed on the cover and extends from an interior of the rear cover to an exterior of the rear cover so as to drive the cover to slide between the first position and the second position.

Preferably, in an embodiment, the covering means further comprises a position-limiting component for limiting the position of the switch when the cover is in the first position and the second position, respectively.

Preferably, in an embodiment, the heat-dissipating means is a fan.

Preferably, in an embodiment, the heat-dissipating means are fins.

Preferably, in an embodiment, the fins are projected beyond a supporting surface of the support which is used for supporting the flat electronic device.

Preferably, in an embodiment, the height of the fins projected beyond the supporting surface are configured so that the fins are able to pass through the heat-dissipating opening to thermally contact with the heat-generating means when the flat electronic device is placed on the support.

Preferably, in an embodiment, a power interface is disposed on the support. Through the power interface, the flat electronic device placed on the support is able to be charged.

Preferably, in an embodiment, a heat-conducting component is disposed in the heat-dissipating opening such that the heat-conducting component is against the heat-generating means when the housing is mounted to the flat electronic device.

The housing for a flat electronic device provided by an embodiment in accordance with the present invention enables the covering means to be operated according to the heat condition of the flat electronic device, and prevents significant heat accumulation in the flat electronic device, so as to solve the problems in the conventional art where the accumulated heat limits the performance of the flat electronic device.

Various simplified concepts are incorporated into this summary of various embodiments of the invention, which will be further described in more detail in the detailed description. This summary of various embodiments of the invention neither implies that it is intended to limit the essential features and necessary technical features of the technical solutions to be protected, nor implies that it is intended to define the scope of the technical solutions to be protected.

Advantages and features of various embodiments in accordance with the present invention will be described in detail below in connection with the accompanying drawings.

While particular embodiments in accordance with the invention have been specifically described within this Summary, it is noted that the invention and the claimed subject matter are not limited in any way by these embodiments.

### BRIEF DESCRIPTION OF THE DRAWINGS

The following drawings of various embodiments in accordance with the present invention are used for understanding of the present invention. The various embodiments and the descriptions thereof are for explaining the principles of various embodiments in accordance with the present invention. In the drawings,

FIG. 1A is a schematic view of a housing for a flat electronic device according to one embodiment of the invention; wherein a covering means is open;

FIG. 1B is a schematic view of a housing for a flat electronic device according to one embodiment of the invention; wherein a covering means is closed; and

FIG. 2 is a schematic view of a support for a flat electronic device according to another embodiment of the invention.

### DETAILED DESCRIPTION

Reference will now be made in detail to various embodiments in accordance with the invention, examples of which are illustrated in the accompanying drawings. While the invention will be described in conjunction with various embodiments, it will be understood that these various embodiments are not intended to limit the invention. On the contrary, the invention is intended to cover alternatives, modifications and equivalents, which may be included within the scope of the invention as construed according to the Claims. Furthermore, in the following detailed description of various embodiments in accordance with the invention, numerous specific details are set forth in order to provide a thorough understanding of the invention. However, it will be evident to one of ordinary skill in the art that the invention may be practiced without these specific details or with equivalents thereof. In other instances, well known methods, procedures, components, and circuits have not been described in detail as not to unnecessarily obscure aspects of the invention.

Various embodiments in accordance with the present invention relate generally to heat dissipation technology, in particular, to a housing, a support, and a heat-dissipating assembly (or system) for a flat electronic device (including a tablet, a flat mobile phone such as iPhone, etc.).

Plenty of specific details are presented in the description below so as to provide a more thorough understanding of the present invention. However, the present invention may be implemented without one or more of these details, as is evident to those skilled in the art. In other examples, some of the technical features known in the art are not described so as to avoid confusion with the present invention.

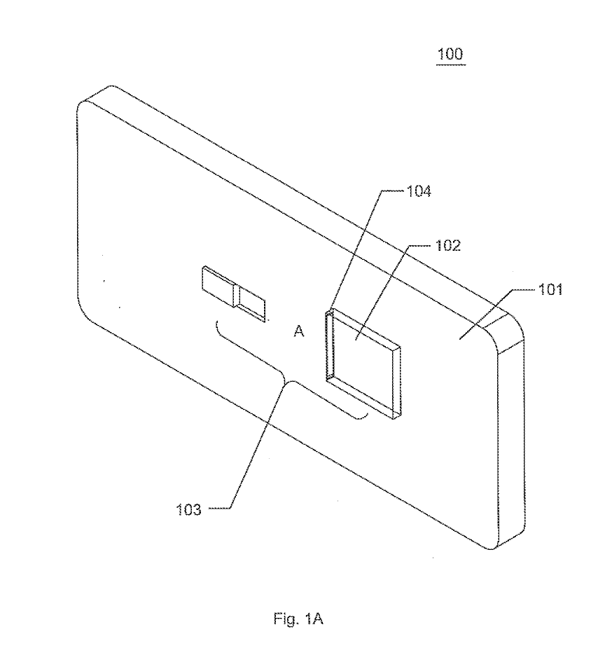

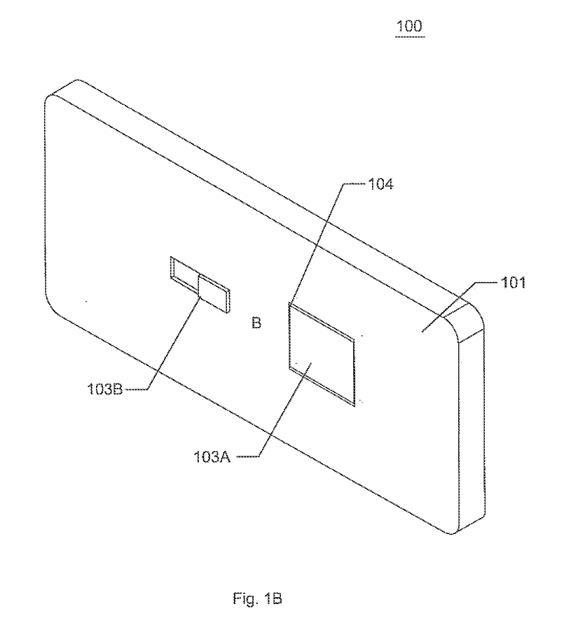

According to one embodiment of the invention, a housing 100 for the flat electronic device (hereinafter referred to as the housing 100) is provided, as shown in FIG. 1A. A heat-dissipating opening 102 is disposed on the rear cover 101 of the housing 100. The heat-dissipating opening 102 is disposed in correspondence with a heat-generating means of the flat electronic device (such as a processor, etc.), so as to diffuse the heat generated by the heat-generating means when working into the environment through the heat-dissipating opening 102. Although the heat-dissipating opening 102 illustrated in FIG. 1A is rectangular, it is apparent to those skilled in the art that the heat-dissipating opening 102 may have any shape through which the heat can be diffused to the environment. The heat-dissipating opening 102 may be disposed to directly expose at least a part of the heat-generating means of the flat electronic device, for example, to expose ¾ or all of the heat-generating means. Similarly, although the shape of the housing 100 illustrated in the figures is generally a cube, the present invention is not intended to be limited to it.

To increase the convenience in use, in an embodiment, a covering means 103 may also be disposed on the rear cover 101 of the housing 100, and the covering means 103 is configured to enable the heat-dissipating opening 102 to be opened and closed. FIG. 1A is a schematic view illustrating that the covering means 103 is open. When the covering means 103 is open, the heat-generating means can thermally communicate with the outside through the heat-dissipating opening 102, so as to dissipate heat through the heat-dissipating opening 102. FIG. 1B is a schematic view illustrating that the covering means 103 is closed. When the covering means 103 is closed, the covering means 103 can completely cover the heat-dissipating opening 102 to protect the heat-generating means of the flat electronic device and prevent the dust. Of course, it will influence the heat dissipation when the covering means 103 closes the heat-dissipating opening 102. Therefore, the user may control the opening and closing of the covering means 103 according to the actual condition. In the event that the heat-generating means is a processor, in an embodiment, the covering means 103 may be operated to close the heat-dissipating opening 102 when the running speed of the processor is lower (for example, the flat electronic device is standing by and is carried in the pocket by the user), while the covering means 103 may be operated to open the heat-dissipating opening 102 when the running speed of the processor is higher (for example, the flat electronic device is used as a Set Box or a Game Console). The covering means 103 may have any structure which is configured to enable the heat-dissipating opening 102 to be opened and closed. Below, the covering means 103 according to one embodiment of the present invention will be described in detail in combination with the accompanying drawings.

Preferably, in an embodiment, a heat-conducting component (not shown) is disposed in the heat-dissipating opening 102. In an embodiment, when the covering means 103 covers the heat-dissipating opening 102, the heat-conducting component is located inside the covering means 103. The heat-conducting component is against the heat-generating means when the housing 100 is mounted on the flat electronic device, such that the heat generated by the heat-generating means may diffuse to the outside via the heat-conducting component through the heat-dissipating opening 102. The heat-conducting component may be made of a metal with higher thermal conductivity and may be in the shape of a plane or a mesh, etc. In this case, the heat-dissipating opening 102 may expose at least a part of the heat-conducting component. Besides being able to transfer the heat of the heat-generating means, the heat-conducting component may also, to some extent, act to protect the heat-generating means. In this way, the covering means 103 may be opened even in the case that a collision could easily happen, such as movement, etc., and thus, it reduces the limit of the performance of the flat electronic device due to the heat dissipation.

As an example, in an embodiment, the covering means 103 is slidably disposed on the housing 100. The heat-dissipating opening 102 is open when the covering means 103 slides to a first position A (referring to FIG. 1A), and the heat-dissipating opening 102 is closed when the covering means 103 slides to a second position B (referring to FIG. 1 B), such that the heat-dissipating opening 102 may be opened and closed conveniently through sliding the covering means 103. The user may make a decision to open the heat-dissipating opening 102 or not, even to leave it in a half-closed state, according to the heat generated by the heat-generating means.

Preferably, in an embodiment, at least a part of the covering means 103 may be disposed inside the rear cover 101 of the housing 100 to ensure that the outer surface of the housing 100 is smooth. According to a preferred embodiment of the invention, a sliding groove 104 is disposed on the inner surface of the rear cover 101 of the housing 100. The covering means 103 comprises a cover 103A and a switch 103B, and the cover 103A is slidably disposed in the sliding groove 104. The sliding groove 104 may surround the cover 103A as illustrated in FIG. 1A, or, it may only limit the upper and lower sides of the cover 103A. The sliding groove 104 may also be disposed in other ways, as long as it can allow the cover 103A to slide therein. The cover 103A may have a shape which is suitable for that of the heat-dissipating opening 102, so as to enable the heat-dissipating opening 102 to be closed. The switch 103B is disposed on the cover 103A and extends from the interior to the exterior of the rear cover 101. That is to say, the switch 103B connects to the cover 103A in the interior of the rear cover 101 and passes through the rear cover 101 such that the user can drive the cover 103A to slide between the first position A and the second position B by moving the switch 103B.

Further, in an embodiment, the covering means 103 further comprises a position-limiting component (not shown) which is used for limiting the position of the switch 103B when the cover 103A is in the first position A (the switch 103B is in an open position) and the second position B (the switch 103B is in a closed position), respectively. That is to say, there is a need to apply an external force to remove the switch 103B from the open position or the closed position. As an example, in an embodiment, the position-limiting component may be protrusions disposed nearby the open position and the closed position of the switch 103B. When removing the cover 103A from the first position A, the user need apply an external force to the switch 103B such that it is able to pass the protrusion nearby the open position and remove it from the open position. The protrusion at the closed position may have the same arrangement as that. Of course, the position-limiting component may also have other structures, as long as it can limit the switch 103B in the open and closed positions when the cover 103A is in the first and second positions A and B, respectively.

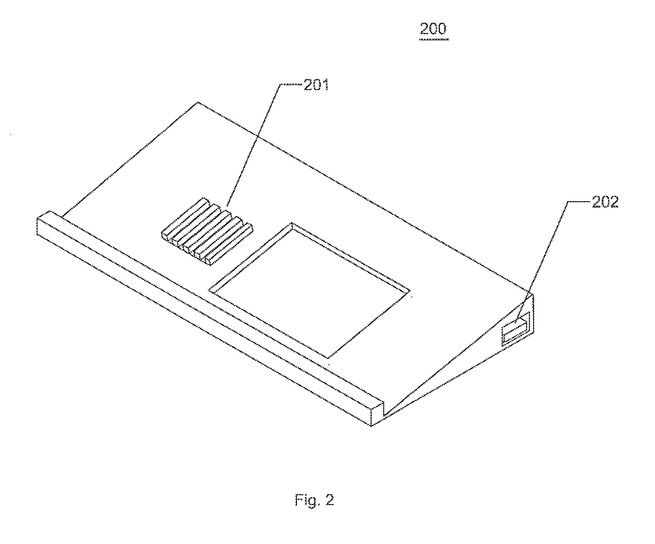

According to another embodiment of the invention, a support 200 for the flat electronic device (hereinafter referred to as the support 200) is provided, as shown in FIG. 2. A heat-dissipating means 201 is disposed on the support 200. The support 200 is used for supporting the flat electronic device (not shown) which has any housing, as mentioned above. The position of the heat-dissipating means 201 is corresponding to the position of the heat-dissipating opening (referring to the heat-dissipating opening 102 in FIG. 1A) of the rear cover 101 of the housing 100 of the flat electronic device when the flat electronic device is placed on the support 200. The heat-dissipating means 201 may diffuse the heat generated by the heat-generating means of the flat electronic device effectively when the flat electronic device is placed on the support 200, to improve the heat-dissipating efficiency and avoid the heat generated by the flat electronic device during high-speed work (or operation) having a negative effect on the electronic element.

As an example, in an embodiment, the heat-dissipating means 201 may be a fan. As an example, in an embodiment, the heat-dissipating means 201 may also be fins. Preferably, in an embodiment, the fins are projected over the supporting surface of the support 200 which is used for supporting the flat electronic device, as shown in FIG. 2. As an example, in an embodiment, the height of the fins projected over the supporting surface are disposed that the fins are able to pass through the heat-dissipating opening 102 to thermally contact with the heat-generating means when the flat electronic device is placed on the support 200, such that the heat-generating means of the flat electronic device can thermally contact with the fins when the flat electronic device is placed on the support 200. The fins may contact with the heat-generating means directly to transfer heat when the heat-dissipating opening 102 (referring to FIG. 1A) exposes the heat-generating means directly. In the case that a heat-conducting component is also disposed in the heat-dissipating opening 102, the heat-conducting component contacts with the fins and is against the heat-generating means (as mentioned above) so as to make a thermal contact between the fins and the heat-generating means.

Further, in an embodiment, a power interface 202 may also be disposed on the support 200, through which the flat electronic device placed on the support 200 is able to be charged. The power interface 202 may be an USB-B type interface, a mini USB interface, or a micro USB interface, etc.

According to another embodiment of the invention, a heat-dissipating assembly or system for the flat electronic device (hereinafter referred to as the heat-dissipating assembly or system) is also provided. The heat-dissipating assembly comprises any housing and any support as mentioned above. A heat-dissipating opening is disposed on the rear cover of the housing and disposed in correspondence with the heat-generating means of the flat electronic device. A covering means is also disposed on the rear cover of the housing, and the covering means is configured to enable the heat-dissipating opening to be opened and closed. A heat-dissipating means is disposed on the support, and the support is used for supporting the flat electronic device. The position of the heat-dissipating means is corresponding to the position of the heat-dissipating opening when the flat electronic device is placed on the support. In an embodiment, each component contained in the heat-dissipating assembly (or system) may refer to the description of the respective part above.

In conclusion, the housing for a flat electronic device provided by various embodiments in accordance with the present invention enables the covering means to be operated according to the heat condition of the flat electronic device, and prevents significant heat accumulation in the flat electronic device, so as to solve the problems that exist in the conventional art where the accumulated heat limits the performance of the flat electronic device.

The present invention has been described by the various above-mentioned embodiments. However, it will be understand that the various above-mentioned embodiments are for the purpose of demonstration and description and not for the purpose of limiting the present invention to the scope of the various described embodiments. Moreover, those skilled in the art can appreciate that the present invention is not limited to the above-mentioned embodiments and that various modifications and adaptations in accordance with the teaching of the present invention may be made within the scope and spirit of the present invention. The protection scope of the present invention is further defined by the following claims and equivalent scope thereof.

The foregoing descriptions of various specific embodiments in accordance with the invention have been presented for purposes of illustration and description. They are not intended to be exhaustive or to limit the invention to the precise forms disclosed, and many modifications and variations are possible in light of the above teaching. The invention is to be construed according to the Claims and their equivalents.

What is claimed is:

1. A housing for an electronic device comprising:
a rear cover that defines a heat-dissipating opening disposed in correspondence with a heat-generating means of the electronic device; and
a covering means disposed on the rear cover of the housing, the covering means enables the heat-dissipating opening to be opened and closed.

2. The housing of claim 1, wherein the covering means is slidably disposed on the housing.

3. The housing of claim 2, further comprising a sliding groove disposed on an inner surface of the rear cover of the housing.

4. The housing of claim 3, wherein the covering means comprises a cover and a switch, the cover is slidably disposed in the sliding groove.

5. The housing of claim 1, further comprising a heat conducting component disposed in the heat-dissipating opening such that the heat-conducting component contacts the heat-generating means when the housing is mounted to the electronic device.

6. A support for an electronic device comprising:
a heat-dissipating means is disposed on the support;
the position of the heat-dissipating means corresponds to the position of a heat-dissipating opening of a rear cover of a housing of the electronic device when the electronic device is placed on the support.

7. The support of claim 6, wherein the heat-dissipating means is a fan.

8. The support of claim 6, wherein the heat-dissipating means are fins.

9. The support of claim 8, wherein the fins are projected beyond a supporting surface of the support, which is used for supporting the electronic device.

10. The support of claim 6, further comprising a power interface disposed on the support for charging the electronic device.

11. A heat-dissipating system for an electronic device comprising:
a housing for the electronic device, the housing comprising:
a heat-dissipating opening disposed on a rear cover of the housing, the heat-dissipating opening disposed in correspondence with a heat-generating means of the electronic device;
a covering means disposed on the rear cover of the housing, the covering means enables the heat-dissipating opening to be opened and closed; and
a support for the electronic device, the support comprising:
a heat-dissipating means is disposed on the support;
the position of the heat-dissipating means corresponds to the position of the heat-dissipating opening when the electronic device is placed on the support.

12. The heat-dissipating system of claim 11, wherein the covering means is slidably disposed on the housing.

13. The heat-dissipating system of claim 12, wherein the housing further comprising a sliding groove is disposed on an inner surface of the rear cover of the housing.

14. The heat-dissipating system of claim 13, wherein the covering means comprises a cover and a switch, the cover is slidably disposed in the sliding groove.

15. The heat-dissipating system of claim 11, wherein the heat-dissipating means is a fan.

16. The heat-dissipating system of claim 11, wherein the heat-dissipating means are fins.

17. The heat-dissipating system of claim 16, wherein the fins are projected beyond a supporting surface of the support.

18. The heat-dissipating system of claim 17, wherein the fins pass through the heat-dissipating opening to thermally contact with the heat-generating means when the electronic device is placed on the support.

19. The heat-dissipating system of claim 11, further comprising a power interface disposed on the support for charging the electronic device.

20. The heat-dissipating system of claim 11, wherein the housing further comprising a heat conducting component disposed in the heat-dissipating opening such that the heat-conducting means contacts the heat-generating component when the housing is mounted to the electronic device.
